(19) United States
(12) Patent Application Publication
(10) Pub. No.: US 2009/0085085 A1
(43) Pub. Date: Apr. 2, 2009

(54) DRAM CELL WITH CAPACITOR IN THE METAL LAYER

(76) Inventors: James Chyi Lai, Saint Paul, MN (US); Tom Allen Agan, Saint Paul, MN (US)

Correspondence Address: PATTERSON & SHERIDAN, L.L.P., 3040 POST OAK BOULEVARD, SUITE 1500, HOUSTON, TX, 77056, US

(21) Appl. No.: 11/865,601

(22) Filed: Oct. 1, 2007

(51) Int. Cl. H01L 27/108

(52) U.S. Cl. 257/306; 257/E27.084

(57) ABSTRACT

A DRAM cell includes a substrate, a transistor, and a capacitor. The substrate is composed of semiconductor material with a main surface, the transistor is formed at the main surface, and the capacitor is formed in a metal layer. The transistor includes a source region and a drain region formed at the main surface of the substrate. The transistor also includes a control gate placed between the source region and the drain region, and separated from the substrate by a thin control dielectric. The capacitor includes a first electrode layer, a dielectric layer formed on the surface of the first electrode layer, and a second electrode layer formed on the surface of the dielectric layer. The DRAM cell increases the density and simplifies the manufacturing process. A DRAM cell with the capacitor formed in multiple layers is also provided.

### BACKGROUND OF THE INVENTION

1. Field of the Invention

The present invention relates to a DRAM cell. More particularly, the present invention relates to a DRAM cell with the capacitor in the metal layer.

2. Description of the Related Art

A Dynamic Random Access Memory (DRAM) cell including a transistor and a storage capacitor per bit has become the most important storage element in electronic system, especially in computer and communication system. The output voltage of a DRAM cell is proportional to the capacitance value of the storage capacitor of the DRAM cell and, therefore, the storage capacitor must have a satisfactory capacitance value to have stable operation of the cell as the applied voltage is scaled.

Furthermore, in a conventional DRAM cell structure, the capacitor is created in the crystal silicon layer because of the need for higher valued capacitance than is typically obtained in the other layers. Also, the capacitor is typically placed adjacent to the transistor and consumes a relatively large and valuable area on the wafer to obtain the needed capacitance values. This makes a DRAM cell large and affects the size of each bit.

However, the main determinant of a DRAM's cost is the density of the memory cells. The goal is to have small-sized memory cells, which means that more of them can be produced at once from a single silicon wafer. This can improve yield, thus reduces the cost.

There are several types of DRAM memory cells that are already available to increase the density, and those memory cells can be divided according to the structure of the capacitor for storing electric charge for information. For example, a trench-type capacitor is formed by forming a deep trench in a semiconductor substrate without increasing the surface area of the semiconductor substrate. The trench-type capacitor can reduce the size of a DRAM cell, but the manufacturing process is difficult and complicated.

For the forgoing reasons, there is a need for a new DRAM cell, so that the density of a DRAM may be increased and the process is simplified, which reduces the cost of manufacturing.

### SUMMARY OF THE INVENTION

The present invention is directed to a DRAM cell that satisfies this need of increasing the density of the memory device and simplifying the manufacturing process.

It is therefore an objective of the present invention to provide a small-sized DRAM cell that miniaturize the structure of memory cells in a DRAM, thus lowering the cost of fabrication, increasing the speed of DRAM integrated circuits, and reducing the leakage and the power consumed by DRAM integrated circuits can be achieved.

It is another objective of the present invention to reduce the area the capacitor occupies by creating it in the metal layer.

It is still another objective of the present invention to provide another small-sized DRAM cell with the capacitor built with multiple layers to provide additional capacitance.

Two embodiments of the present invention are described. The first embodiment is a DRAM cell with the capacitor formed in a metal layer. According to the first embodiment of the present invention, a DRAM cell comprises a substrate, a transistor, and a capacitor. The substrate is composed of semiconductor material with a main surface, the transistor is formed at the main surface, and the capacitor is formed in a metal layer above the transistor. The transistor includes a source region and a drain region formed at the main surface of the substrate. The transistor also includes a control gate placed between the source region and the drain region, and separated from the substrate by a thin control dielectric. The capacitor includes a first electrode layer, a dielectric layer formed on the surface of the first electrode layer, and a second electrode layer formed on the surface of the dielectric layer.

The second embodiment is a DRAM cell with the capacitor formed in multiple layers. According to the second embodiment of the present invention, a DRAM cell comprises a substrate, a transistor, and a capacitor. The substrate is composed of semiconductor material with a main surface, the transistor is formed at the main surface, and the capacitor is formed in multiple metal layers. The transistor includes a source region and a drain region formed at the main surface of the substrate. The transistor also includes a control gate placed between the source region and the drain region, and separated from the substrate by a thin control dielectric. The capacitor is built with multiple layers to provide the desired capacitance when the invention scales to smaller dimensions or when one single layer does not provide sufficient capacitance.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a side cross-sectional view of the DRAM cell according to a first preferred embodiment of this present invention; and

FIG. 2 is a side cross-sectional view of the DRAM cell according to a second preferred embodiment of this present invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

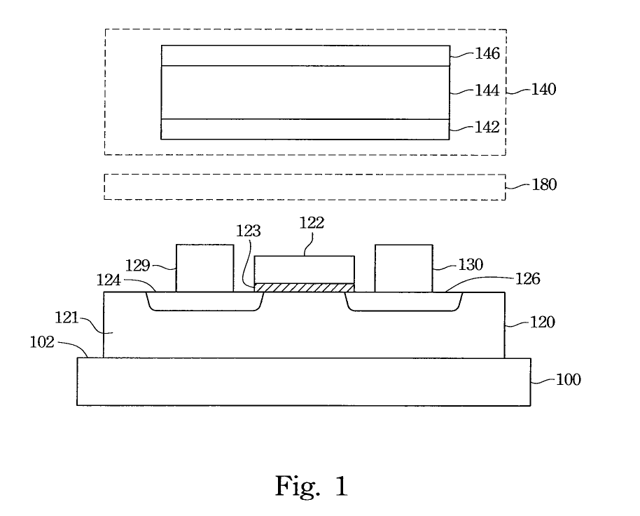

Please refer to FIG. 1. FIG. 1 is a cross-sectional view of the DRAM cell according to a first embodiment of the present invention. A DRAM cell includes a substrate 100, a transistor 120, and a capacitor 140. The substrate 100 is composed of semiconductor material with a main surface 102. The transistor 120 includes a source region 124 and a drain region 126 formed at the main surface 102 of the substrate 100. The transistor 120 also includes a control gate 122 placed between the source region 124 and the drain region 126, and separated from the substrate 100 by a thin control dielectric 123. The control gate 122 is polysilicon, and the thin control dielectric 123 may be silicon dioxide. The capacitor 140 includes a first electrode layer 142, a dielectric layer 144 formed on the surface of the first electrode layer 142, and a second electrode layer 146 formed on the surface of the dielectric layer 144.

Notice that the capacitor 140 is formed in the metal layer above the transistor 120. Conventional capacitors are created in the crystal silicon layer to obtain higher valued capacitance; however, modern capacitors are capable of obtaining the needed DRAM capacitance values when they are created in the metal layer. As a result, the capacitor 140 can be formed above the transistor 120 in the metal layer. However, the capacitor 140 does not need to be created directly above the transistor 120. When the capacitor 140 is moved from the crystal silicon layer to the metal layer, the overall area of the DRAM cell can be significantly reduced. Besides, the necessary wiring connections for the DRAM cell can be placed in a routing area 180, located in between the transistor 120 and the capacitor 140, to achieve greater intensity.

Furthermore, the capacitance values of modern capacitors have increased dramatically, with dielectric constants over 3000, thinner dielectrics, and surface roughness. This allows that the capacitor 140 can take up less space than the transistor 120. Note that even though the gate length of the transistor 120 is very small, the capacitor 140 has the area for the entire transistor 120, including contacts 129 and 130, the control gate 122 and a diffusion area 121.

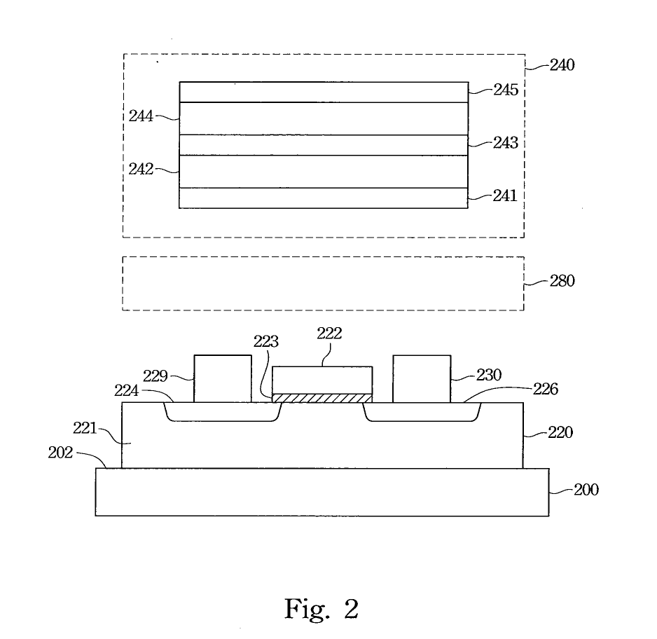

Please refer to FIG. 2, a cross-sectional view of the DRAM cell according to a second preferred embodiment of this present invention. A DRAM cell includes a substrate 200, a transistor 220, and a capacitor 240. The substrate 200 is composed of semiconductor material with a main surface 202. The transistor 220 includes a source region 224 and a drain region 226 formed at the main surface 202 of the substrate 200. The transistor 220 also includes a control gate 222 placed between the source region 224 and the drain region 226, and separated from the substrate 200 by a thin control dielectric 223. The control gate 222 is polysilicon, and the thin control dielectric 223 may be silicon dioxide. The capacitor 240 includes a first electrode layer 241, a second dielectric layer 242 formed on the surface of the first electrode layer 241, a third electrode layer 243 formed on the surface of the second dielectric layer 242, a forth dielectric layer 244 formed on the surface of the third electrode layer 243, and a fifth electrode layer 245 formed on the surface of the forth dielectric layer 244.

Modern capacitors are capable of obtaining the needed DRAM capacitance values when they are created in the metal layer. As a result, the capacitor 240 can be formed above the transistor 220. However, the capacitor 240 does not need to be created directly above the transistor 220. When the capacitor 240 is created in the metal layer, the overall area of the DRAM cell can be significantly reduced.

Notice that the capacitor 240 is built in multiple metal layers with the first electrode layer 241, the third electrode layer 243, and the fifth electrode layer 245. When the capacitor does not provide sufficient capacitance with a single layer of capacitance, multiple layers can be placed to provide the desired capacitance. In addition, this invention allows for scaling to smaller dimensions because the capacitor size relative to the transistor size remains about the same. As the size of the transistor gets smaller, the amount of current it can handle also gets smaller. That is when the DRAM cell requires larger amount of capacitance relative to the size of the transistor. The capacitor can be built with multiple metal layers to provide the additional capacitance. So, in this second embodiment, the first electrode layer 241, the third electrode layer 243, and the fifth electrode layer 245 are placed to provide the desired capacitance for the transistor 220.

Besides, the necessary wiring connections for the DRAM cell can be placed in a routing area 280, located in between the transistor 220 and the capacitor 240, to achieve greater intensity. Lastly, the capacitance values of modern capacitors have increased dramatically, with dielectric constants over 3000, thinner dielectrics, and surface roughness. This allows that the capacitor 240 can take up less space than the transistor 220. Note that even though the gate length of the transistor 220 is very small, the capacitor 240 has the area for the entire transistor 220, including contacts 229 and 230, the control gate 222 and a diffusion area 221.

The difference between the first and the second embodiment is that the capacitor in the second embodiment is built with multiple layers to provide the desired capacitance when the invention scales to small dimensions or one single layer does not provide sufficient capacitance.

From the description above, we can conclude that this invention of a small-sized DRAM cell satisfies the need of increasing the density of the DRAM cells, thus lowers the cost of fabrication. The small-sized DRAM cell is achieved by creating the capacitor in the metal layer, and has the capability of increasing the speed of DRAM integrated circuits and reducing the leakage and the power consumed by DRAM integrated circuits.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A DRAM cell, comprising:
a substrate having semiconductor material with a main surface;
a transistor formed at the main surface; and
a capacitor formed in a metal layer located above the transistor.

2. The DRAM cell of claim 1, wherein the transistor includes:
a source region;
a drain region; and
a control gate placed between the source region and the drain region and separated from the substrate by a thin control dielectric.

3. The DRAM cell of claim 1, wherein the capacitor includes:
a first electrode layer;
a dielectric layer formed on the surface of the first electrode layer; and
a second electrode layer formed on the surface of the dielectric layer.

4. The DRAM cell of claim 1, further comprising a routing area between the transistor and the capacitor for the wiring connections of the DRAM cell.

5. A DRAM cell, comprising:
a substrate having semiconductor material with a main surface;
a transistor formed at the main surface; and
a capacitor formed in a plurality of metal layers located above the transistor;
wherein the plurality of metal layers provide the desired capacitance when the DRAM cell requires more capacitance.

6. The DRAM cell of claim 5, wherein the transistor includes:
a source region;
a drain region; and
a control gate placed between the source region and the drain region and separated from the substrate by a thin control dielectric.

7. The DRAM cell of claim 5, wherein the capacitor includes:
a plurality of electrode layers; and
a plurality of dielectric layers;
wherein the plurality of dielectric layers are formed between the plurality of electrode layers.

8. The DRAM cell of claim 5, further comprising a routing area between the transistor and the capacitor for the wiring connections of the DRAM cell.
